(19) United States
(12) Patent Application Publication
(10) Pub. No.: US 2006/0267647 A1
(43) Pub. Date: Nov. 30, 2006

(54) Method and circuit for controlling spread spectrum phase locked loop

(75) Inventor: Tung Yen Chang, Hsinchu City (TW)

Correspondence Address: TROXELL LAW OFFICE PLLC, ONE SKYLINE PLACE, 5205 LEESBURG PIKE, SUITE 1404, FALLS CHURCH, VA, 22041, US

(73) Assignee: Sunplus Technology Co., Ltd.

(21) Appl. No.: 11/316,816

(22) Filed: Dec. 27, 2005

(30) Foreign Application Priority Data
May 25, 2005 (TW) 094117047

(51) Int. Cl. H03L 7/06

(52) U.S. Cl. 327/156

(57) ABSTRACT

A spread spectrum phase locked loop control circuit includes a reference frequency divider, a phase detector, a charge pump, a filter circuit, a voltage controlled oscillator circuit, and a modulation control circuit. With these components, the output frequency of the voltage controlled oscillator circuit can be spread evenly in a fixed range and the energy can be distributed evenly. The invention also describes a method for controlling the spread spectrum phase locked loop.

### BACKGROUND OF THE INVENTION

1. Field of the Invention

The present invention relates to a method and circuit for controlling spread spectrum phase locked loop, and more particularly to a method and circuit for controlling spread spectrum phase locked loop capable of oscillating or modulating the output frequency of a voltage controlled oscillator circuit to evenly spread its output frequency within a fixed range and evenly distribute the energy.

2. Description of the Related Art

Electromagnetic interference (EMI) increasingly becomes a serious issue as the system operating frequency rises. After a phase locked loop (PLL) is modulated, a spread spectrum frequency will be produced to significantly improve the EMI issue of a high-speed circuit. Therefore, most of the present high-speed chips adopt a spread spectrum function.

To accomplish a better spread spectrum effect, a modulation control circuit is added to the phase locked loop (PLL), and a pattern generator and a digital-to-analog converter (DAC) are generally added to a low-pass filter, but the complicated pattern generator with a 5-level digital-to-analog converter not only make the control more complicated and the area of the chip larger, but also delay the time of research and development and increase costs.

In 1994, an article “Spread Spectrum Clock Generation for the Reduction of Radiated Emission” written by K. B. Hardin et al and published in the IEEE International Symposium on Electromagnetic Compatibility disclosed that different modulated waveforms of the phase locked loop give different results. In 1997, K. B. Hardin et al further published an article “Design Considerations of Phase locked Loop System for Spread Spectrum Clock Generation” in IEEE International Symposium on Electromagnetic Compatibility and disclosed that the best modulated waveform is obtained by a modulation circuit division, and the shortcomings of such modulation reside on its complicated control and its requirements for increasing the frequency, and thus increasing the size of resistors and capacitors of a low-pass filter and resulting in an increase of manufacturing costs.

Referring to FIG. 1a for the schematic view of a prior art spread spectrum phase locked loop, the prior art spread spectrum phase locked loop 40 comprises: a reference frequency divider 41; a phase detector 42; a low-pass filter circuit 43; a voltage controlled oscillator circuit 44; and a feedback divider 45. The general modulation feedback frequency divider 45 achieves the spread spectrum function by inputting a constant control frequency to the divisor change of the feedback divider 45 or directly inputting constant modulated signals to the low-pass filter circuit 43. If a modulation is carried out directly to the feedback divider 45, the modulation control waveform VCOIN produced looks like a sine wave as shown in FIG. 1C. Therefore, the spectrum analysis indicates that the energy drops and two rises are produced even though the spread spectrum is wide as shown in FIG. 1B, and thus creating a limitation to the spread spectrum function.

Referring to FIG. 2 for the schematic view of the structure of another prior art phase locked loop system, this phase locked loop system 50 comprises: a reference frequency divider 51; a phase detector 52; a charge pump 53; a filter circuit 54; a voltage controlled oscillator circuit 55; a modulation control circuit 56; and a feedback divider 57. Similar modulated waveforms are introduced to the low-pass filter 54 to produce a fine-tuning modulation on the low-pass filter 54, and such design requires an increase of capacitance and minimizes the charging current. However, increasing the capacitance causes an increase of price and reducing the current makes the design difficult.

Refer to FIGS. 3a and 3b respectively for the schematic views of a prior art spread spectrum output and its optimal modulation control waveform VCOIN. In FIG. 3a, the waveform of a modulation controlled signal VCOIN disclosed by Lexmark indicates that the modulation control waveform VCOIN can eliminate the two rises as depicted in FIG. 1a, but the density of its central energy is higher than that shown in FIG. 1B, and FIG. 1B shows that both ends have a groove which causes a limitation to the spread spectrum.

Refer to FIGS. 4a, 4b and 4c for the schematic views of a prior art spread spectrum phase locked loop system outputting a constant frequency that will cause an uneven frequency output. In FIG. 4b, if the frequency VCOIN of the voltage controlled oscillator circuit is constant, different VCOIN amplitudes result in different frequencies on their spectra as shown in FIG. 4c, and their distributions are uneven as shown in FIG. 4c. After the waveforms of the VCOIN are overlapped for many times, various energy distributions (dBm) of different frequencies are obtained, since they output a constant frequency. Therefore, FIG. 4c shows the unevenness (as indicated by the depressions in the figure) among different frequencies.

In view of the description above, a method and circuit for controlling spread spectrum phase locked loop is needed to carry out an amplitude modulation or a frequency modulation to an output frequency of the voltage controlled oscillator circuit, such that the spectrum of its output frequency can be spread evenly within a fixed range, and its energy can be distributed evenly to improve the foregoing shortcomings.

### SUMMARY OF THE INVENTION

The primary objective of the present invention is to provide a circuit for controlling a spread spectrum phase locked loop that can carry out an amplitude modulation to an output frequency signal of the voltage controlled oscillator circuit, such that its output frequency can be spread evenly within a fixed range, and its energy can be distributed evenly.

Another objective of the present invention is to provide a circuit for controlling a spread spectrum phase locked loop that can carry out a frequency modulation to an output frequency signal of the voltage controlled oscillator circuit, such that its output frequency can be spread evenly within a fixed range, and its energy can be distributed evenly.

A further objective of the present invention is to provide a circuit for controlling a spread spectrum phase locked loop that can carry out a fine tuning to the spread spectrum control, so that the output frequency can be intensified to achieve the modulation of the spread spectrum with the less increase of spread spectrum control circuit. There is no need to add a pattern generator and a digital-to-analog converter (DAC). Therefore, the present invention can lower the manufacturing costs.

Another further objective is to provide a method for controlling a spread spectrum phase locked loop that can carry out an amplitude modulation or a frequency modulation to produce a variable modulated waveform such that its output frequency can be spread evenly within a fixed range and its energy can be distributed evenly.

To achieve the foregoing objectives, the circuit for controlling a spread spectrum phase locked loop comprises: a reference frequency divider coupled to a clock signal, and outputting a reference clock signal after carrying out a frequency division; a phase detector coupled to reference frequency divider for carrying out a phase detection to the reference clock signal and outputting an up counting output and a down counting output; a charge pump coupled to a phase detector for charging electricity according to the up counting output and the down counting output; a filter circuit coupled to a charge pump for producing a voltage controlled oscillation input signal after filtering an output signal of the charge pump; a voltage controlled oscillator circuit coupled to a filter circuit for outputting a voltage controlled oscillation output signal and an output clock signal according to the voltage controlled oscillation input signal; and a modulation control circuit coupled to a voltage controlled oscillator circuit for producing a spread spectrum modulation signal and outputting the spread spectrum modulation signal to the phase detector after carrying out a modulation to the voltage controlled oscillation output signal.

To achieve the foregoing objectives, the method of controlling a spread spectrum phase locked loop comprises the steps of: using a phase locked loop to carry out a frequency multiplication and a phase lock to a reference signal; and carrying out a modulation to an output signal of an oscillating circuit of the phase locked loop by a digital control method when the spectrum of the reference signal is spread, such that the output frequency of the oscillating circuit can be spread evenly within a fixed range, and the energy can be distributed evenly.

To make it easier for our examiner to understand the structure, characteristics and objectives of the present invention, a preferred embodiment accompanied with its related drawings will be described as follows:

### BRIEF DESCRIPTION OF THE DRAWINGS

FIG. 1a is a schematic view of a prior art spread spectrum phase locked loop;

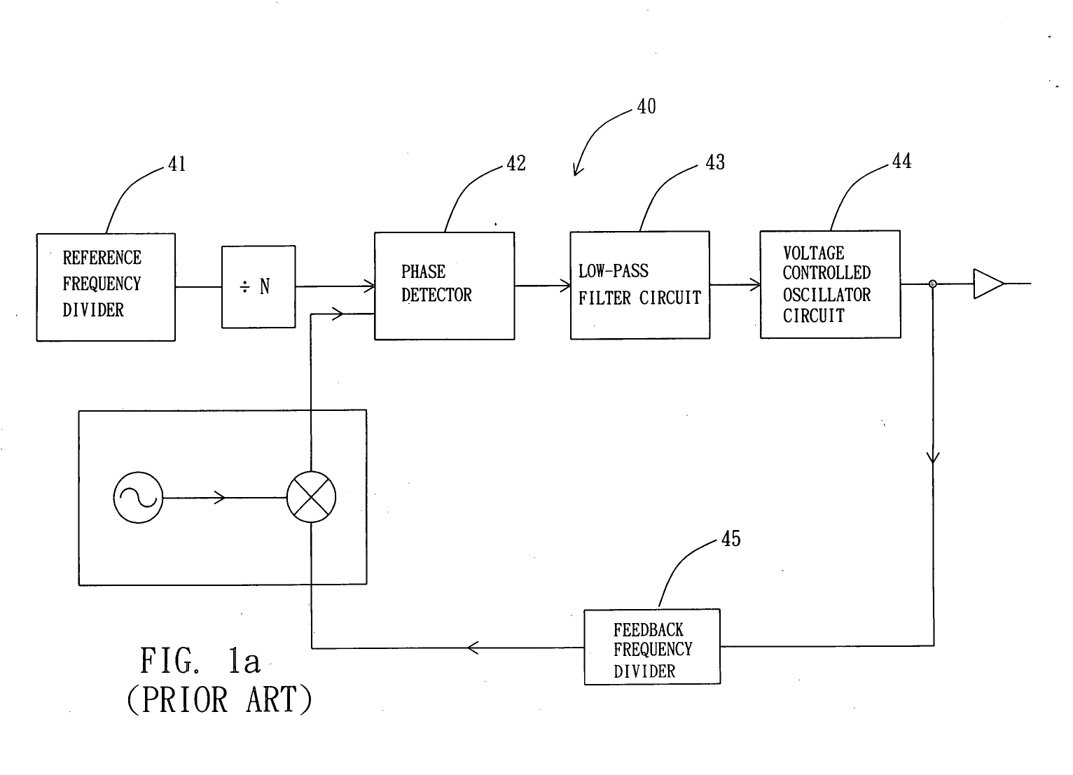

FIG. 1b is a schematic view of another prior art spread spectrum phase locked loop producing two rises during a spectrum spread;

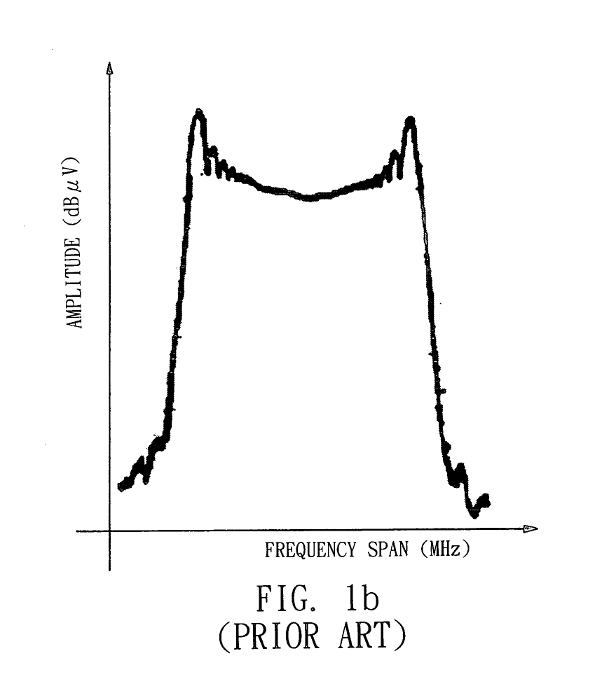

FIG. 1c is a schematic view of a prior art spread spectrum lock phase loop modulation control waveform VCOIN being similar to a sine wave;

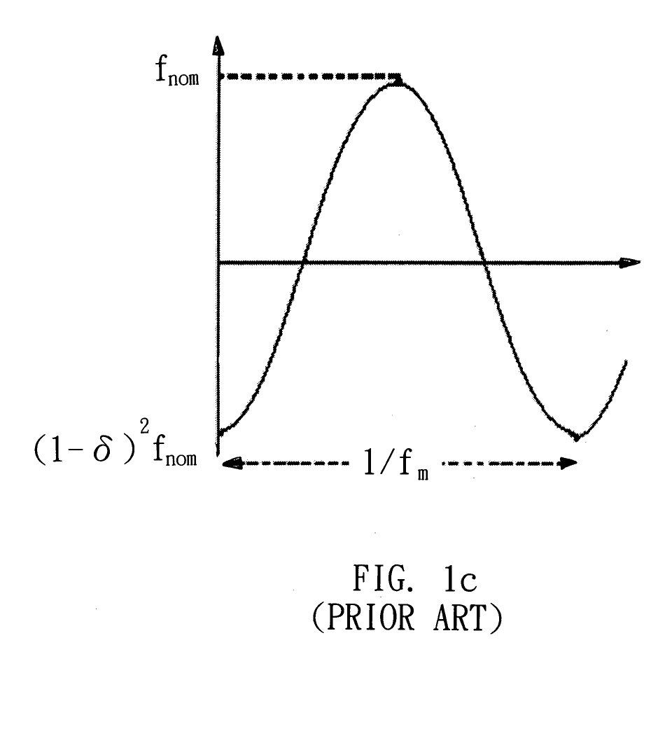

FIG. 2 is a schematic view of the structure of another prior art lock phase loop system;

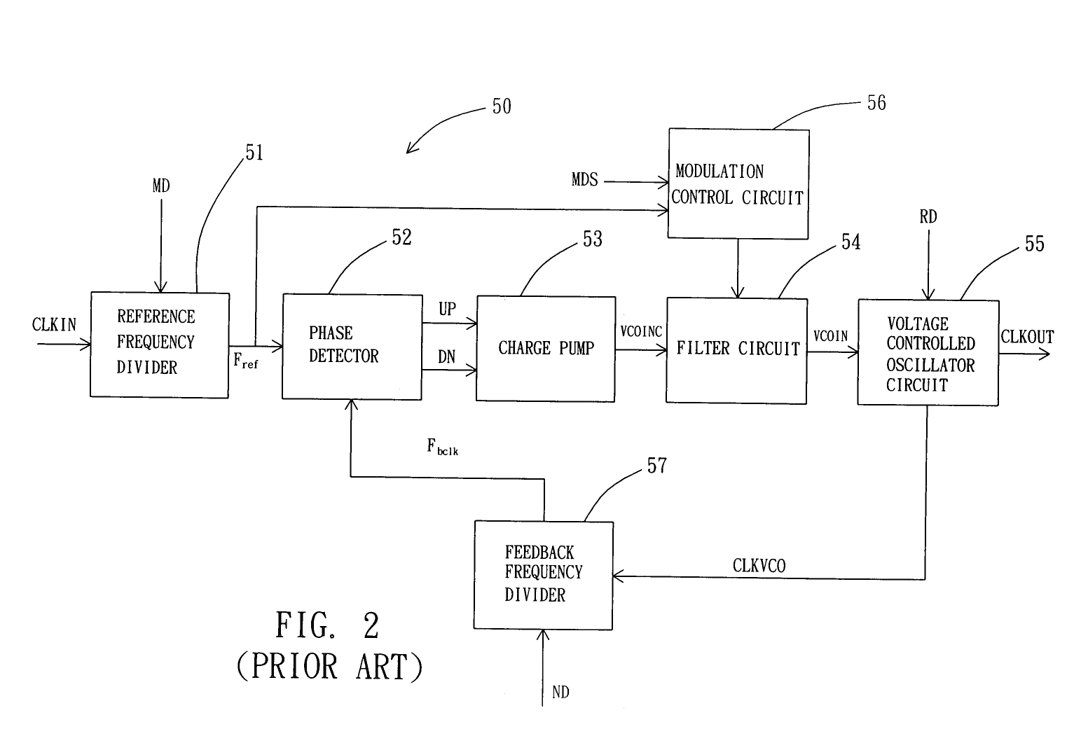

FIGS. 3a and 3b are schematic views of a prior art spread spectrum output and its optimal modulation control waveform VCOIN respectively;

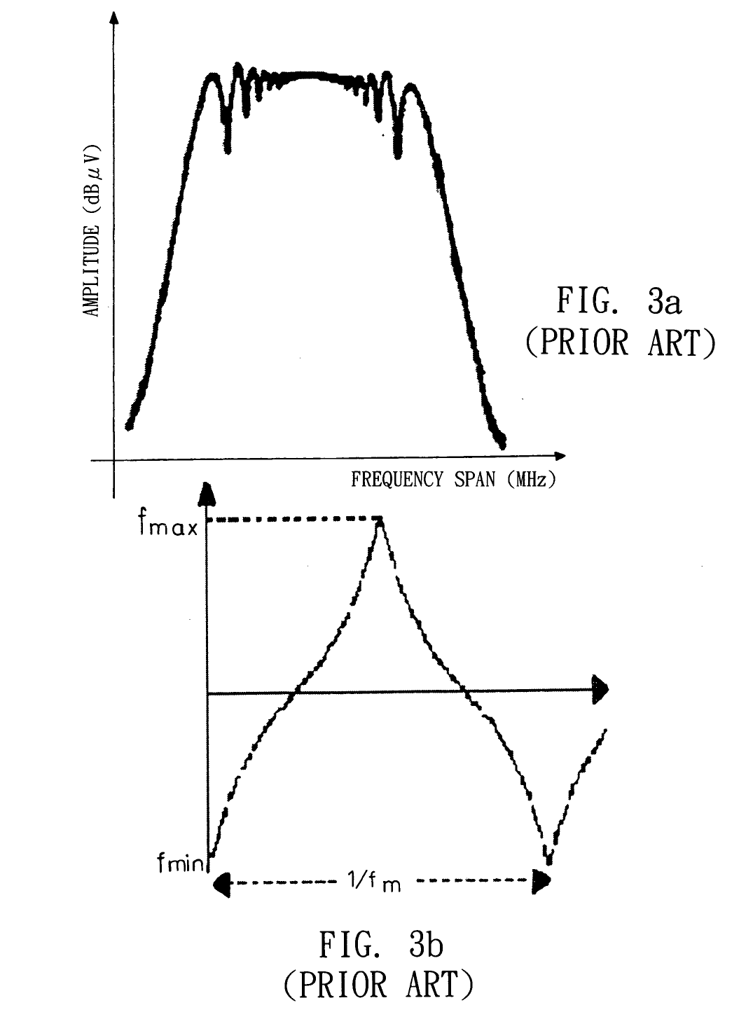

FIGS. 4a, 4b and 4c are schematic views of a prior art spread spectrum lock phase loop system outputting a constant frequency to cause an uneven frequency output;

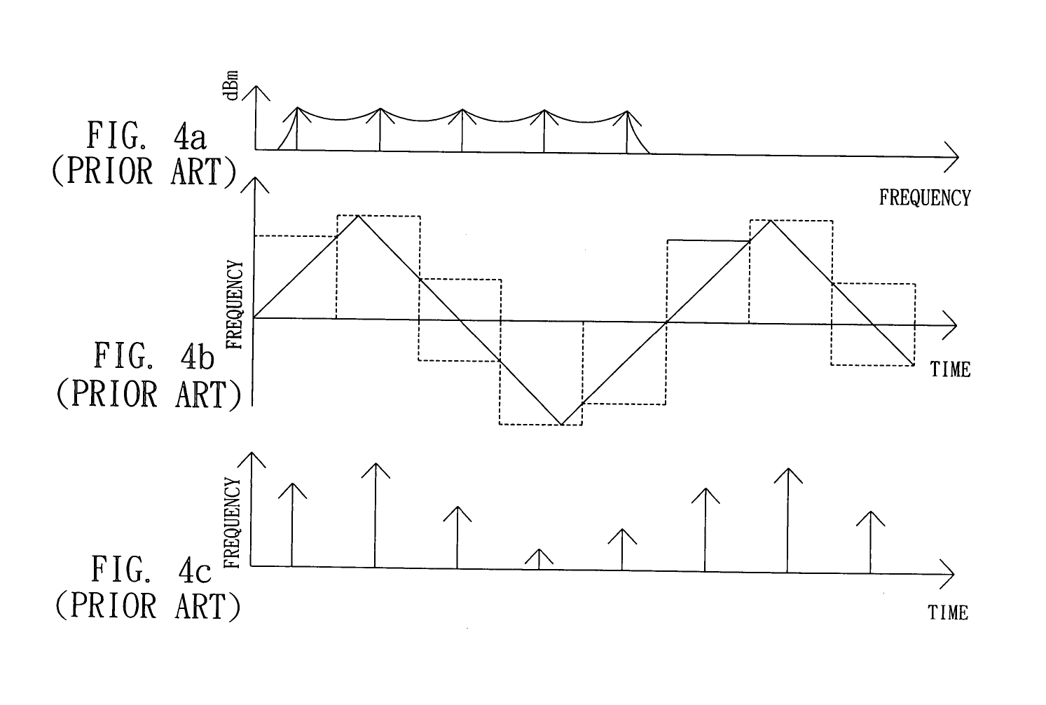

FIG. 5 is a schematic block diagram of a control circuit of a lock phase loop according to a preferred embodiment of the present invention;

FIGS. 6a, 6b, and 6c are schematic views of an output frequency, a VCOIN and an energy output after a modulation control circuit carries out an amplitude modulation to a voltage controlled oscillation output signal CLKVCO according to the present invention;

FIGS. 7Aa, 7b, and 7c are schematic views of an output frequency, a VCOIN and an energy output after a modulation clock control circuit carries out a frequency modulation to a voltage controlled oscillation output signal CLKVCO according to the present invention; and

FIG. 8 is a flow chart of a method of controlling a spread frequency lock phase loop according to the present invention.

### DETAILED DESCRIPTION OF THE PREFERRED EMBODIMENTS

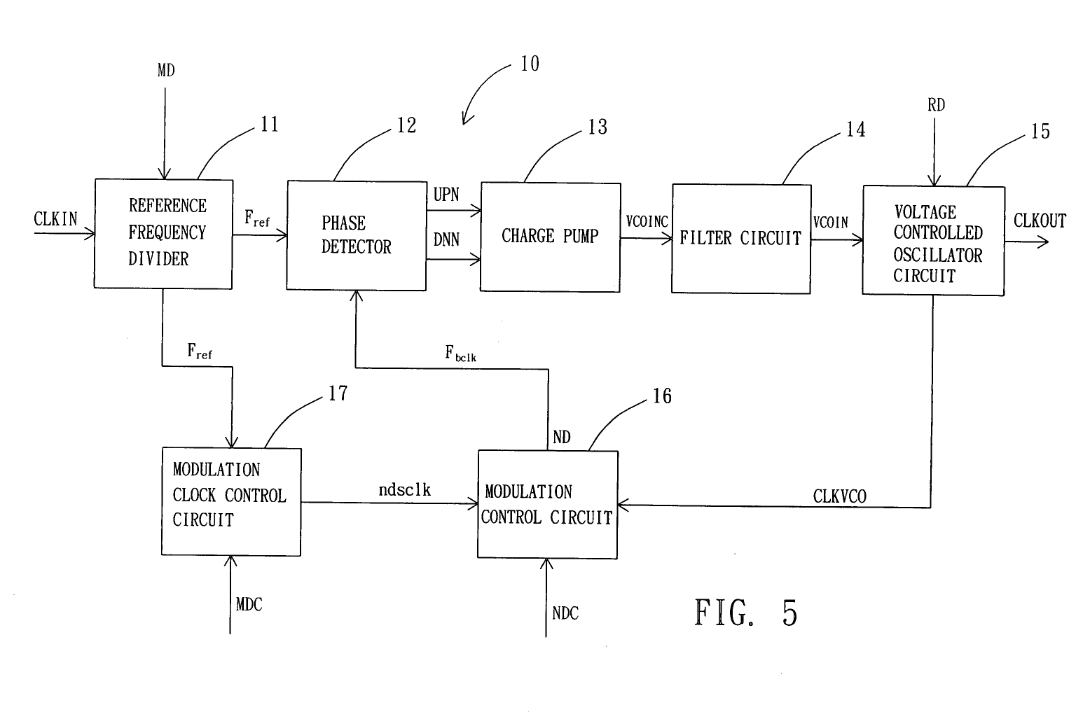

Referring to FIG. 5 for the schematic block diagram of a circuit for controlling a spread spectrum phase locked loop according to a preferred embodiment of the present invention, the circuit 10 for controlling the spread spectrum phase locked loop is a module-two digital phase locked loop, comprising a reference frequency divider 11; a phase detector 12; a charge pump 13; a filter circuit 14; a voltage controlled oscillator circuit 15; and a modulation control circuit 16.

The reference frequency divider 11 is coupled to a clock signal CLKIN for outputting a reference clock signal F_{ref} after a frequency is divided. The frequency of the reference signal is preferably 100 MHz.

The phase detector 12 is coupled to the reference frequency divider 11 for carrying out a phase detection to the reference clock signal F_{ref} and outputting an up counting output UPN and a down counting output DNN to the charge pump 13.

The charge pump is coupled to the phase detector 12 for charging or discharging electricity according to the up counting output UPN and the down counting output DNN.

The filter circuit 14 is preferably a low-pass filter circuit coupled to the charge pump 13 for producing a voltage controlled oscillation input signal VCOIN after filtering the output signal VCOINC of the charge pump 13. The low-pass filter circuit is preferably consisted of a capacitor and a resistor. The frequency of the reference signal Fret is 100 MHz, and the voltage controlled oscillation input signal VCOIN is a triangle wave, and preferably a triangle wave with a frequency ranging from 30 KHz to 60 KHz.

The voltage controlled oscillator circuit 15 is coupled to the filter circuit 14 for outputting a voltage controlled oscillation output signal CLKVCO and an output clock signal CLKOUT according to the voltage controlled oscillation input signal VCOIN.

The modulation control circuit 16 is coupled to the voltage controlled oscillator circuit 15 for producing a spread spectrum modulation signal F_{bclk} and outputting the spread spectrum modulation signal F_{bclk} to the phase detector 12 after carrying out a modulation to the voltage controlled oscillation output signal CLKVCO; wherein the modulation control circuit 16 carries out an amplitude modulation or a frequency modulation to the voltage controlled oscillation output signal CLKVCO. The sequence of the amplitude modulation is programmable and can be pre-stored in the modulation control circuit 16.

In addition, the circuit 10 for controlling the spread spectrum phase locked loop further comprises a modulation clock control circuit 17 coupled to the reference frequency divider 11 and modulation control circuit 16 for outputting a modulation controlled system clock signal MDSCLK to the modulation control circuit 16 according to a modulation controlled signal MDC and a reference clock signal F_{ref}, so that the modulation control circuit 16 outputs the spread spectrum modulation signal F_{bclk} to the phase detector 12. The sequence of the frequency modulation is programmable and can be pre-stored into the modulation clock control circuit 17,

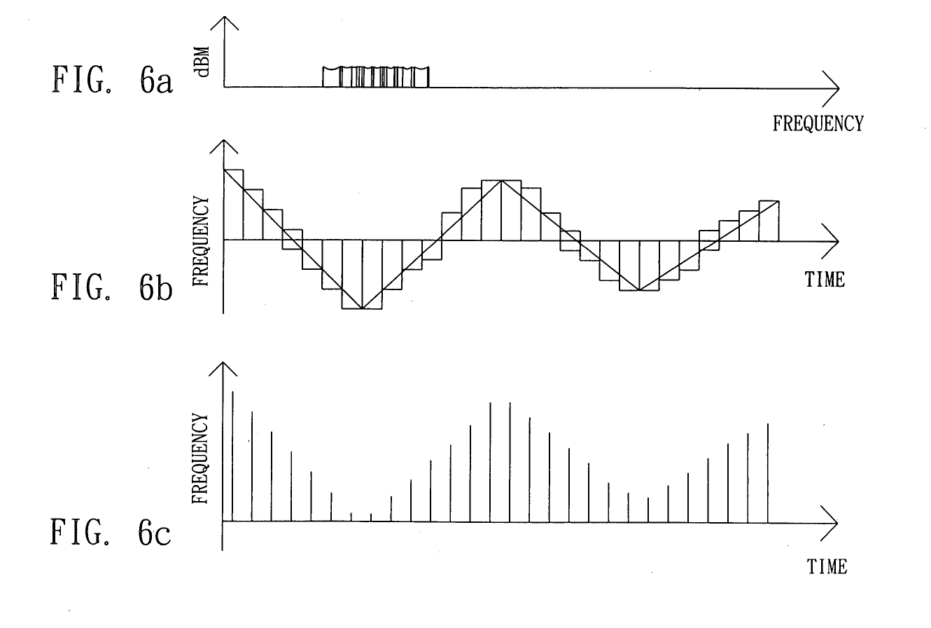

Referring to FIGS. 6a, 6b, and 6c for the schematic views of an output frequency, a VCOIN and an energy output after the modulation control circuit 16 carries out an amplitude modulation to the voltage controlled oscillation output signal CLKVCO according to the present invention. The principle of the modulation control circuit 16 carrying out the amplitude modulation to the voltage controlled oscillation output signal CLKVCO according to the present invention is described below, and the basic assumption of parameters is also given as follows:
CLKVCO Modulation profile: triangle wave
Modulation Clock: Fₘ
Modulation Clock Period: Tₘ
VCO Max Frequency: Fₘₐₓ and its control voltage: Vₘₐₓ
VCO Min Frequency: Fₘᵢₙ and its control voltage: Vₘᵢₙ
VCO Center Frequency: F_{cm} and its control voltage: V_{cm},
where
V_{cm}=(Vₘₐₓ+Vₘᵢₙ)/2
AVG VCO Gain: kₒ, where kₒ=(Fₘₐₓ−Fₘᵢₙ)/(Vₘₐₓ−Vₘᵢₙ)
VCO Transfer Function: F_{vco}=F(t)=F_{cm}+kₒ*(V_{cm}−V(t)),
where,
V(t)=V_{cm}+(Vₘₐₓ−Vₘᵢₙ)/(Tₘ/2)*t, in 0<t<Tₘ/4
V(t)=Vₘₐₓ−(Vₘₐₓ−Vₘᵢₙ)/(Tₘ/2)*(t−Tₘ/4), in Tₘ/4<t<3*Tₘ/4
V(t)=Vₘᵢₙ+(Vₘₐₓ−Vₘᵢₙ)/(Tₘ/2)*(t−3*Tₘ/4), in 3*Tₘ/4<t<Tₘ
Assumed that Fₘ=100 KHz, Tₘ=10 μS, F_{cm}=100 MHz, Fₜₒₚ=103 MHz, F_{bottom}=97 MHz and V_{cm}=1V, kₒ=100 MHz/V, Vₜₒₚ=1.03V, V_{bottom}=0.97V, then
V(t)=1V+0.012V/μS*t, in 0<t<Tₘ/4
V(t)=1.03V−0.012V/μS*(t−Tₘ/4), in Tₘ/4<t<3*Tₘ/4
V(t)=0.97V+0.012V/μS*(t−3*Tₘ/4), in 3*Tₘ/4<t<Tₘ
In a modulation clock period (10 μS), there exists 1000 F_{vco} periods.

$$In 0 < t < {T}_{m} / 4$$

$$V ( t ) = 1 V + 0.012 V / μ S * t$$

$$\begin{matrix}F ( t ) = 100 MHz + 100 MHz / V * ( 1 V - 1 V + 0.012 V / μ S * t ) \\ = 100 MHz + ( 1.2 / μ S * t ) MHz\end{matrix}$$

$$\begin{matrix}{F}_{1} = F ( 10 μ S / 1000 ) \\ = 100 MHz + ( 1.2 / μ S * 10 μ S / 1000 ) MHz \\ = 100 MHz + 0.012 MHz\end{matrix}$$

$$\begin{matrix}{F}_{ 2} = F ( 10 μ S / 1000 * 2 ) \\ = 100 MHz + 0.012 * 2 MHz \\ = 100 MHz + 0.024 MHz\end{matrix}$$

The n^{th} frequency is
Fₙ=F(10 μS/1000*n)=100 MHz+0.012*n*MHz
If the amplitude of the CLKVCO modulation signal of the next modulation is 0.012V*Aₛ (Amplitude), and Aₛ=0.999, then

$$In 0 < t < {T}_{m} / 4$$

$$\begin{matrix}V ( t ) = 1 V + 0.012 V / μ S * t * {A}_{s} \\ = 1 V + 0.012 V / μ S * t * 0.999 \\ = 1 V + 0.011988 V / μ S * t\end{matrix}$$

$$\begin{matrix}F ( t ) = 100 MHz + 100 MHz / V * ( 1 V - 1 V + 0.011988 V / μ S * t ) \\ = 100 MHz + ( 1.1988 / μ S * t ) MHz\end{matrix}$$

$$\begin{matrix}{F}_{1} = F ( 10 μ S / 1000 ) \\ = 100 MHz + ( 1.1988 / μ S * 10 μ S / 1000 ) M\end{matrix}$$

$$Hz = 100 MHz + 0.011988 MHz$$

$$\begin{matrix}{F}_{2} = F ( 10 μ S / 1000 * 2 ) \\ = 100 MHz + 0.012 * 2 MHz \\ = 100 MHz + 0.023976 MHz\end{matrix}$$

The n^{th} frequency is
Fₙ=F(10 μS/1000*n)=100 MHz+0.011988*n*MHz
If the amplitude of the CLKVCO modulation signal of the next modulation is 0.012V*Aₛ (Amplitude), and Aₛ=0.998, then

$$In 0 < t < {T}_{m} / 4$$

$$\begin{matrix}V ( t ) = 1 V + 0.012 V / μ S * t * {A}_{s} \\ = 1 V + 0.012 V / μ S * t * 0.998 \\ = 1 V + 0.011976 V / μ S * t\end{matrix}$$

$$\begin{matrix}F ( t ) = 100 MHz + 100 MHz / V * ( 1 V - 1 V + 0.011976 V / μ S * t ) \\ = 100 MHz + ( 1.1976 / μ S * t ) MHz\end{matrix}$$

$$\begin{matrix}{F}_{1} = F ( 10 μ S / 1000 ) \\ = 100 MHz + ( 1.1976 / μ S * 10 μ S / 1000 ) MHz \\ = 100 MHz + 0.01197 MHz\end{matrix}$$

$$\begin{matrix}{F}_{2} = F ( 10 μ S / 1000 * 2 ) \\ = 100 MHz + 0.012 * 2 MHz \\ = 100 MHz + 0.023952 MHz\end{matrix}$$

The n^{th} frequency is
Fₙ=F(10 μS/1000*n)=100 MHz+0.011976*n*MHz
If the amplitude of the CLKVCO modulation signal of the next modulation is 0.012V*Aₛ (Amplitude), and Aₛ=0.997, then

$$In 0 < t < {T}_{m} / 4$$

$$\begin{matrix}V ( t ) = 1 V + 0.012 V / μ S * t * {A}_{s} \\ = 1 V + 0.012 V / μ S * t * 0.997 \\ = 1 V + 0.011964 V / μ S * t\end{matrix}$$

$$\begin{matrix}F ( t ) = 100 MHz + 100 MHz / V * ( 1 V - 1 V + 0.011964 V / μ S * t ) \\ = 100 MHz + ( 1.1964 / μ S * t ) MHz\end{matrix}$$

$$\begin{matrix}{F}_{1} = F ( 10 μ S / 1000 ) \\ = 100 MHz + ( 1.1964 / μ S * 10 μ S / 1000 ) MHz \\ = 100 MHz + 0.011964 MHz\end{matrix}$$

$$\begin{matrix}{F}_{2} = F ( 10 μ S / 1000 * 2 ) \\ = 100 MHz + 0.012 * 2 MHz \\ = 100 MHz + 0.023928 MHz\end{matrix}$$

The n^{th} frequency is
Fₙ=F(10 μS/1000*n)=100 MHz+0.011964*n*MHz

In summation of the description above, if the modulation control circuit 16 of the invention carries out an amplitude modulation to the output frequency VCOIN (which is 0.012V*Aₛ, where Aₛ=1.03-0.97 and can be stored into the modulation control circuit 16) of the voltage controlled oscillator circuit 15, then different VCOIN amplitudes as shown in FIG. 6b can be obtained, and the spectrum of the different VCOIN amplitudes have different frequencies respectively as shown in FIG. 6c. Compared with the constant frequency of the prior art, the output frequency of the present invention is distributed more evenly. Since the period of each modulated VCOIN signal varies, therefore its energy will not be occurred at the constant frequency. After the waveforms of the VCOIN are overlapped for many times, a gentler energy distribution (dBm) will be obtained as shown in FIG. 6a. Compared with the voltage controlled oscillation output signal CLKVCO of the prior art with constant frequency, the present invention can smooth the recessions and thus overcoming the shortcomings of the prior art.

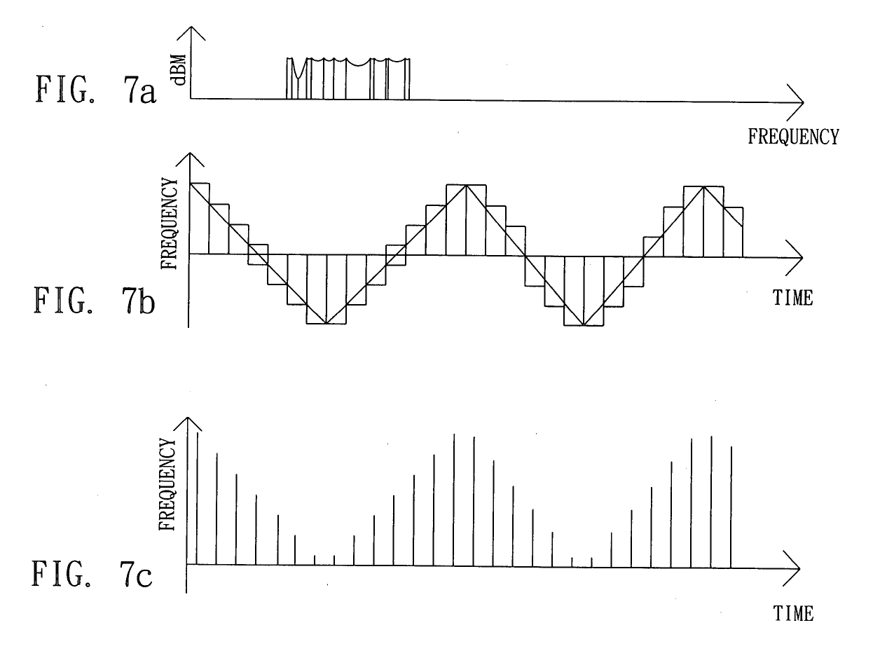

Referring to FIGS. 7a, 7b, and 7c for the schematic views of an output frequency, a VCOIN and an energy output after the modulation clock control circuit 17 carries out a frequency modulation to the voltage controlled oscillation output signal CLKVCO according to the present invention. The principle of the modulation clock control circuit 17 carrying out a frequency modulation to the voltage controlled oscillation output signal CLKVCO according to the present invention is described below and the basic assumption of parameter is also given as follows:
CLKVCO Modulation profile: triangle wave
Modulation Clock: Fₘ
Modulation Clock period: Tₘ
VCO Max Frequency: Fₘₐₓ and its control voltage: Vₘₐₓ
VCO Min Frequency: Fₘᵢₙ and its control voltage: Vₘᵢₙ
VCO Center Frequency: F_{cm} and its control voltage: V_{cm}, V_{cm}=(Vₘₐₓ+Vₘᵢₙ)/2
   VCO Gain: kₒ, kₒ=(Fₘₐₓ−Fₘᵢₙ)/(Vₘₐₓ−Vₘᵢₙ)
   VCO Transfer Function: F_{vco}=F(t)=F_{cm}+kₒ*(V_{cm}−V(t))
   Where,
   V(t)=V_{cm}+(Vₘₐₓ−Vₘᵢₙ)/(Tₘ/2)*t, in 0<t<Tₘ/4
   V(t)=Vₘₐₓ−(Vₘₐₓ−Vₘᵢₙ)/(Tₘ/2)*(t−Tₘ/4), in Tₘ/4<t<3*Tₘ/4
   V(t)=Vₘᵢₙ+(Vₘₐₓ−Vₘᵢₙ)/(Tₘ/2)*(t−3*Tₘ/4), in 3*Tₘ/4<t<Tₘ

Assumed that Fₘ=100 KHz, Tₘ=10 μS, F_{cm}=100 MHz, Fₜₒₚ=103 MHz, F_{bottom}=97 MHz and V_{cm}=1V, kₒ=100 MHz/V, Vₜₒₚ=1.03V, V_{bottom}=0.97V, then
V(t)=1V+0.012V/μS*t, in 0<t<Tₘ/4
V(t)=1.03V−0.012V/μS*(t−Tₘ/4), in Tₘ/4<t<3*Tₘ/4
V(t)=0.97V+0.012V/μS*(t−3*Tₘ/4), in 3*Tₘ/4<t<Tₘ
In the modulation clock period (10 μS), there exists 1000 F_{vco} periods.

$$In 0 < t < {T}_{m} / 4$$

$$V ( t ) = 1 V + 0.012 V / μ s * t$$

$$\begin{matrix}F ( t ) = 100 MHz + 100 MHz / V * ( 1 V - 1 V + 0.012 V / μ S * t ) \\ = 100 MHz + ( 1.2 / μ S * t ) MHz\end{matrix}$$

$$\begin{matrix}{F}_{1} = F ( 10 μ S / 1000 ) \\ = 100 MHz + ( 1.2 / μ S * 10 μ S / 1000 ) MHz \\ = 100 MHz + 0.012 MHz\end{matrix}$$

$$\begin{matrix}{F}_{2} = F ( 10 μ S / 1000 * 2 ) \\ = 100 MHz + 0.012 * 2 MHz \\ = 100 MHz + 0.024 MHz\end{matrix}$$

The n^{th} frequency is
Fₙ=F(10 μS/1000*n)=100 MHz+0.012*n*MHz
If a modulation clock period (9.5 μS) has 950 F_{vco} periods, then

$$In 0 < t < {T}_{m} / 4$$

$$V ( t ) = 1 V + 0.012 V / μ S * t$$

$$\begin{matrix}F ( t ) = 100 MHz + 100 MHz / V * ( 1 V - 1 V + 0.012 V / μ S * t ) \\ = 100 MHz + ( 1.2 / μ S * t ) MHz\end{matrix}$$

$$\begin{matrix}{F}_{1} = F ( 9.5 μ S / 1000 ) \\ = 100 MHz + ( 1.2 / μ S * 9.5 μ S / 1000 ) MHz \\ = 100 MHz + 0.0114 MHz\end{matrix}$$

$$\begin{matrix}{F}_{2} = F ( 9.5 μ S / 1000 * 2 ) \\ = 100 MHz + 0.0114 * 2 MHz \\ = 100 MHz + 0.0228 MHz\end{matrix}$$

The n^{th} frequency is
Fₙ=F(9.5 μS/1000*n)=100 MHz+0.0114*n*MHz
If a modulation clock period (9.0 μS) has 900 F_{vco} periods, then

$$In 0 < t < {T}_{m} / 4$$

$$V ( t ) = 1 V + 0.012 V / μ S * t$$

$$\begin{matrix}F ( t ) = 100 MHz + 100 MHz / V * ( 1 V - 1 V + 0.012 V / μ S * t ) \\ = 100 MHz + ( 1.2 / μ S * t ) MHz\end{matrix}$$

$$\begin{matrix}{F}_{1} = F ( 9 μ S / 1000 ) \\ = 100 MHz + ( 1.2 / μ S * 9 μ S / 1000 ) MHz \\ = 100 MHz + 0.0108 MHz\end{matrix}$$

$$\begin{matrix}{F}_{2} = F ( 9 μ S / 1000 * 2 ) \\ = 100 MHz + 0.0108 * 2 MHz \\ = 100 MHz + 0.0216 MHz\end{matrix}$$

The n^{th} frequency is
Fₙ=F(9 μS/1000*n)=100 MHz+0.0108*n*MHz

In summation of the description above, if the modulation clock control circuit 17 carries out a frequency modulation to the output frequency VCOIN (which is 0.012V*Fₛ, and Fₛ=1.03-0.97 and can be stored into the modulation clock control circuit 17) of the voltage controlled oscillator circuit 15, then the spectrum of different VCOIN periods as shown in FIG. 7b can obtain different frequencies (as shown in FIG. 7c). Compared with the prior art constant frequency, the output frequency of the invention is distributed more evenly. Since each period of the modulated VCOIN varies, therefore its energy will not be occurred at the constant frequency. After the waveforms of the VCOIN are overlapped for many times (such as 1000 times), a gentler energy distribution (dBm) as shown in 7a is obtained. Compared with the voltage controlled oscillation output signal CLKVCO of the prior art with constant frequency, the present invention can smooth the recessions, and thus overcoming the shortcomings of the prior art.

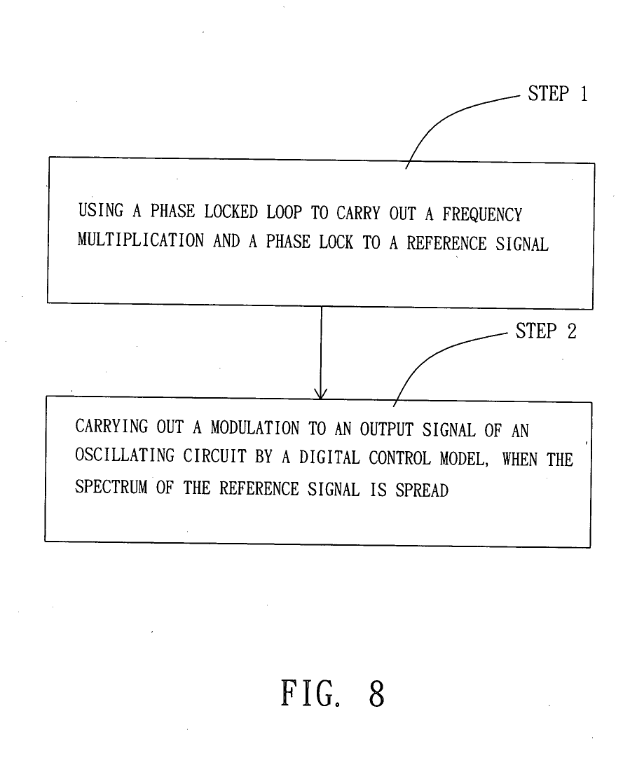

Refer to FIG. 8, the flow chart of a method for controlling spread spectrum phase locked loop according to the present invention, the method of controlling spread spectrum phase locked loop comprises the steps of: (Step 1) using a phase locked loop to carry out a frequency multiplication and a phase lock to a reference signal; (Step 2); carrying out a modulation to an output signal of an oscillating circuit by a digital control method, when the spectrum of the reference signal of the oscillating circuit is spread, such that the output frequency can be spread evenly within a fixed range, and the energy can be distributed evenly.

Referring to FIGS. 5 to 7, the phase locked loop as described in Step 1 is a module-two digital phase locked loop, and the frequency of the reference signal is 100 MHz, and the spread spectrum modulation signal is a triangle wave preferably having a frequency ranging from 30 KHz to 60 KHz.

In Step 2, the oscillating circuit is a voltage controlled oscillator circuit 15, and when the spectrum of the reference signal is spread, an amplitude modulation or a frequency modulation is carried out by a digital control method to the output signal of the oscillating circuit 15. The sequence of the amplitude modulation is programmable, such as 1.03-0.97, and can be pre-stored in the digital phase locked loop, or the sequence of the frequency modulation is programmable, such as 1.03-0.97, and can be pre-stored in the digital phase locked loop, and the spread spectrum is a down spread spectrum or a center spread spectrum. The principle of the actions for this method has been illustrated in FIGS. 5 to 7 and thus will not be described here.

With the implementation of the present invention, a frequency modulation or an amplitude modulation can be carried out to the output signal of the voltage controlled oscillator circuit to produce a variable modulated waveform, so that its output frequency can be spread evenly within a fixed range and its energy can be distributed evenly. The invention requires very little additional circuits for the spread spectrum controller or adds no digital-to-analog controller or complicated pattern generator, and thus can lower the manufacturing costs. The present invention definitely can overcome the shortcomings of the prior art spread spectrum phase locked loop.

In summation of the above description, the present invention herein enhances the performance and overcomes the shortcoming of the prior art, and further complies with the patent application requirements and is submitted to the Patent and Trademark Office for review and granting of the commensurate patent rights.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for controlling spread spectrum phase locked loop, comprising the steps of:
carrying out a frequency multiplication and a phase lock to a reference signal by a phase locked loop; and
modulating an output signal of an oscillation circuit of said phase locked loop by a digital control method, when the spectrum of said reference signal is spread;
such that the output frequency of said oscillation circuit is spread evenly within a fixed range and energy is distributed evenly.

2. The method for controlling spread spectrum phase locked loop of claim 1, wherein said phase locked loop is a module-two digital phase locked loop.

3. The method for controlling spread spectrum phase locked loop of claim 1, wherein said reference signal has a frequency of 100 MHz, and said spread spectrum modulation signal is a triangle wave with a frequency ranging from 30 KHz to 60 KHz.

4. The method for controlling spread spectrum phase locked loop of claim 1, wherein said oscillation circuit is a voltage controlled oscillator circuit.

5. The method for controlling spread spectrum phase locked loop of claim 1, further comprising a step of carrying out an oscillation and an amplitude modulation of the output signal of said oscillation circuit by a digital control method when the spectrum of said reference signal is spread.

6. The method for controlling spread spectrum phase locked loop of claim 5, wherein said amplitude modulation has a programmable sequence and can be pre-stored in said digital phase locked loop.

7. The method for controlling spread spectrum phase locked loop of claim of claim 6, wherein said amplitude modulation ranges from 1.03 to 0.997.

8. The method for controlling spread spectrum phase locked loop of claim 1, wherein said reference signal carries out a frequency modulation to an output signal of said oscillating circuit by a digital control method when the spectrum of said reference signal is spread.

9. The method for controlling spread spectrum phase locked loop of claim 8, wherein said frequency modulation has a programmable sequence and can be pre-stored in said digital phase locked loop.

10. The-method for controlling spread spectrum phase locked loop of claim 8, wherein said frequency modulation ranges from 1.03 to 0.997.

11. The method for controlling spread spectrum phase locked loop of claim 1, wherein said spread spectrum is a down spread spectrum or a center spread spectrum.

12. A circuit for controlling spread spectrum phase locked loop, comprising:
a reference frequency divider, coupled to a clock signal and outputting a reference clock signal after performing a frequency division;
a phase detector, coupled to said reference frequency divider and executing a phase detection to said reference clock signal, and outputting an up counting output and a down counting output;
a charge pump, coupled to phase detector for charging electricity according to said up counting output and down counting output;
a filter circuit, coupled to said charge pump for producing a voltage controlled oscillation input signal after an output signal of said charge pump is filtered;
a voltage controlled oscillator circuit, coupled to filter circuit for outputting a voltage controlled oscillation output signal and an output clock signal according to said voltage controlled oscillation input signal; and
a modulation control circuit, coupled to said voltage controlled oscillator circuit for producing a spread spectrum modulation signal after said voltage controlled oscillation output signal is modulated, and outputting said spread spectrum modulation signal to said phase detector.

13. The circuit for controlling spread spectrum phase locked loop of claim 12, wherein said phase locked loop is a module-two digital phase locked loop.

14. The circuit for controlling spread spectrum phase locked loop of claim 12, wherein said reference signal has a frequency of 100 MHz, and said spread spectrum modulation signal is a triangle wave with a frequency ranging from 30 KHz to 60 KHz.

15. The circuit for controlling spread spectrum phase locked loop of claim 12, wherein said modulation control circuit carries out an amplitude modulation to said voltage controlled oscillation output signal.

16. The circuit for controlling spread spectrum phase locked loop of claim 15, wherein said amplitude modulation has a programmable sequence and can be pre-stored in said modulation control circuit.

17. The circuit for controlling spread spectrum phase locked loop of claim 16, wherein said amplitude modulation ranges from 1.03 to 0.997.

18. The circuit for controlling spread spectrum phase locked loop of claim 12, it further comprising a modulation clock control circuit coupled to said reference frequency divider and said modulation control circuit for outputting a modulation controlled system clock signal to said modulation control circuit according to a modulation controlled signal and a reference clock signal, such that said modulation control circuit outputs said spread spectrum modulation signal to said phase detector.

19. The circuit for controlling spread spectrum phase locked loop of claim 18, wherein said modulation clock control circuit carries out a frequency modulation to said voltage controlled oscillation output signal.

20. The circuit for controlling spread spectrum phase locked loop of claim 19, wherein said frequency modulation has a programmable sequence and can be pre-stored in said modulation clock control circuit.

21. The circuit for controlling spread spectrum phase locked loop of claim 18, wherein said frequency modulation ranges from 1.03 to 0.997.

22. The circuit for controlling spread spectrum phase locked loop of claim 12, wherein said spread spectrum is a down spread spectrum and a center spread spectrum.

23. The circuit for controlling spread spectrum phase locked loop of claim 12, wherein said filter circuit is a low-pass filter circuit.
